(19) United States
(12) Patent Application Publication
(10) Pub. No.: US 2026/0096422 A1
(43) Pub. Date: Apr. 2, 2026

(54) SEMICONDUCTOR DEVICE AND METHOD FOR FABRICATING THE SAME

(71) Applicant: SAMSUNG ELECTRONICS CO., LTD., Suwon-si (KR)

(72) Inventors: Yun Ho KANG, Suwon-si (KR); Myung-Ho KONG, Suwon-si (KR); Suk Hoon Kim, Suwon-si (KR); Yeon Uk KIM, Suwon-si (KR); Jun Hwan MOON, Suwon-si (KR); Do Sun LEE, Suwon-si (KR)

(73) Assignee: SAMSUNG ELECTRONICS CO., LTD., Suwon-si (KR)

(21) Appl. No.: 19/223,865

(22) Filed: May 30, 2025

(30) Foreign Application Priority Data
Sep. 27, 2024 (KR) 10-2024-0131471
Oct. 23, 2024 (KR) 10-2024-0145588

(51) Int. Cl. H01L 23/532; H01L 21/768; H01L 23/535

(52) U.S. Cl. CPC H10W 20/44; H10W 20/0698; H10W 20/20

(57) ABSTRACT

A semiconductor device includes a substrate, a first wiring pattern on an upper surface of the substrate, and a second wiring pattern on the upper surface of the substrate. The first wiring pattern includes a first crystal and a second crystal adjacent to the first crystal in a horizontal direction. A crystal orientation of each of the first crystal and the second crystal is in a vertical direction perpendicular to the upper surface of the substrate. An interface between the first crystal and the second crystal extends in the vertical direction. The second wiring pattern is spaced apart from the first wiring pattern in the horizontal direction.

### CROSS-REFERENCE TO RELATED APPLICATIONS

This application claims priority under 35 U.S.C. § 119 to Korean Patent Application No. 10-2024-0131471, filed on Sep. 27, 2024, and to Korean Patent Application No. 10-2024-0145588, filed on Oct. 23, 2024, in the Korean Intellectual Property Office, the disclosures of which are incorporated by reference herein in their entireties.

### BACKGROUND

### 1. Field

The present disclosure relates generally to semiconductor device, and more particularly, to a semiconductor device including a plurality of wiring patterns and a method for fabricating the semiconductor device.

### 2. Description of Related Art

Recently, along with advancements in electronic technology, demand for down-scaling of semiconductor devices may have increased, which may have led to an increased demand for relatively high integration and/or relatively low power consumption of semiconductor chips. Attempts to achieve the relatively high integration and/or relatively low power consumption may include reducing gaps between circuit components such as, but not limited to, wiring patterns, and/or reducing the distance between wiring patterns. However, these reductions may increase the resistance of the wiring patterns, as well as, reduce a reliability of the semiconductor devices. Thus, there exists a need for further improvements in semiconductor device technology, as the need for improved reliability of the semiconductor devices may be constrained by the resistance of fine wiring patterns. Improvements are presented herein. These improvements may also be applicable to other semiconductor technologies.

### SUMMARY

One or more example embodiments of the present disclosure provide a semiconductor device with enhanced electrical characteristics, when compared to related semiconductor devices, by reducing the resistance of the wiring pattern, as well as a method for fabricating the same.

Aspects of the present disclosure are not limited to those mentioned above and another aspect which is not mentioned may be clearly understood by those skilled in the art from the description below.

According to an aspect of the present disclosure, a semiconductor device includes a substrate, a first wiring pattern on an upper surface of the substrate, and a second wiring pattern on the upper surface of the substrate. The first wiring pattern includes a first crystal and a second crystal adjacent to the first crystal in a horizontal direction. A crystal orientation of each of the first crystal and the second crystal is in a vertical direction perpendicular to the upper surface of the substrate. An interface between the first crystal and the second crystal extends in the vertical direction. The second wiring pattern is spaced apart from the first wiring pattern in the horizontal direction.

According to an aspect of the present disclosure, a semiconductor device includes a substrate, and a wiring pattern on an upper surface of the substrate. The wiring pattern includes a first crystal and a second crystal adjacent to the first crystal in a horizontal direction. A crystal orientation of each of the first crystal and the second crystal is in a vertical direction perpendicular to the upper surface of the substrate. An interface between the first crystal and the second crystal extends in the vertical direction. A height of the second crystal in the vertical direction is equal to a height of the first crystal in the vertical direction. An upper surface of the second crystal and an upper surface of the first crystal are formed on a first plane. A bottom surface of the second crystal and a bottom surface of the first crystal are formed on a second plane.

According to an aspect of the present disclosure, a method for fabricating a semiconductor device includes forming a first sacrificial pattern and a second sacrificial pattern spaced apart in a horizontal direction on an upper surface of a substrate, forming a first wiring material layer at least partially covering sidewalls and an upper surface of the first sacrificial pattern, and a second wiring material layer at least partially covering sidewalls and an upper surface of the second sacrificial pattern on the upper surface of the substrate, forming a protective layer at least partially covering each of the first wiring material layer and the second wiring material layer, at least partially filling a space between the first wiring material layer and the second wiring material layer on the upper surface of the substrate, separating the first wiring material layer into a first wiring pattern and a second wiring pattern spaced apart from the first wiring pattern in the horizontal direction, and separating the second wiring material layer into a third wiring pattern and a fourth wiring pattern spaced apart from the third wiring pattern in the horizontal direction by performing a planarization process to at least partially expose the upper surface of each of the first sacrificial pattern and the second sacrificial pattern, and etching the first sacrificial pattern, the second sacrificial pattern, and the protective layer. The forming of the first wiring material layer and the second wiring material layer includes exposing the upper surface of the substrate between the first wiring material layer and the second wiring material layer. The first wiring material layer includes a first crystal and a second crystal adjacent to the first crystal in the horizontal direction. A crystal orientation of each of the first crystal and the second crystal on sidewalls of the first sacrificial pattern in the horizontal direction being vertical and perpendicular to the upper surface of the substrate. An interface between the first crystal and the second crystal on sidewalls of the first sacrificial pattern in the horizontal direction extending in the vertical direction.

Additional aspects may be set forth in part in the description which follows and, in part, may be apparent from the description, and/or may be learned by practice of the presented embodiments.

### BRIEF DESCRIPTION OF THE DRAWINGS

The above and other aspects, features, and advantages of certain embodiments of the present disclosure may be more apparent from the following description taken in conjunction with the accompanying drawings, in which:

FIG. 1 is a layout diagram for explaining a semiconductor device, according to some exemplary embodiments of the present disclosure;

FIG. 2 is a cross-sectional view taken along line A-A′ of FIG. 1, according to some exemplary embodiments of the present disclosure;

FIGS. 3 to 9 are intermediate stage diagrams for explaining a method for fabricating a semiconductor device shown in FIGS. 1 and 2, according to some exemplary embodiments of the present disclosure;

FIG. 10 is a cross-sectional view for explaining a semiconductor device, according to several exemplary embodiments of the present disclosure;

FIG. 11 is an intermediate stage diagram for explaining a method for fabricating a semiconductor device shown in FIG. 10, according to some exemplary embodiments of the present disclosure;

FIG. 12 is a cross-sectional view for explaining a semiconductor device, according to several exemplary embodiments of the present disclosure;

FIG. 13 is a cross-sectional view for explaining a semiconductor device, according to several exemplary embodiments of the present disclosure;

FIG. 14 is a cross-sectional view for explaining a semiconductor device, according to several exemplary embodiments of the present disclosure;

FIG. 15 is a cross-sectional view for explaining a semiconductor device, according to several exemplary embodiments of the present disclosure;

FIG. 16 is a cross-sectional view for explaining a semiconductor device, according to several exemplary embodiments of the present disclosure;

FIGS. 17 to 21 are intermediate stage diagrams for explaining a method for fabricating a semiconductor device shown in FIG. 16, according to some exemplary embodiments of the present disclosure;

FIG. 22 is a cross-sectional view for explaining a semiconductor device, according to some exemplary embodiments of the present disclosure;

FIG. 23 is a cross-sectional view for explaining a semiconductor device, according to some exemplary embodiments of the present disclosure; and

FIGS. 24 and 25 are intermediate stage diagrams for explaining a method for fabricating a semiconductor device shown in FIG. 23, according to some exemplary embodiments of the present disclosure.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to”another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

In the present disclosure, the articles “a” and “an” are intended to include one or more items, and may be used interchangeably with “one or more. ” Where only one item is intended, the term “one” or similar language may be used. For example, the term “a device” may refer to either a single device or to multiple devices. When a device is described as carrying out an operation and the device is referred to perform an additional operation, the multiple operations may be executed by either a single device or any one or a combination of multiple devices.

As used herein, each of the terms “Al₂O₃”, “C₃H₆O”, “Cr₂AlC”, “PdCoO₂”, “PdCrO₂”, “PtCoO₂”, “Si₃N₄”, “Si₂N₂O”, “SiO₂”, “V₂AlC”, and the like may refer to a material made of elements included in each of the terms and is not a chemical formula representing a stoichiometric relationship.

Hereinafter, various embodiments of the present disclosure are described with reference to the accompanying drawings.

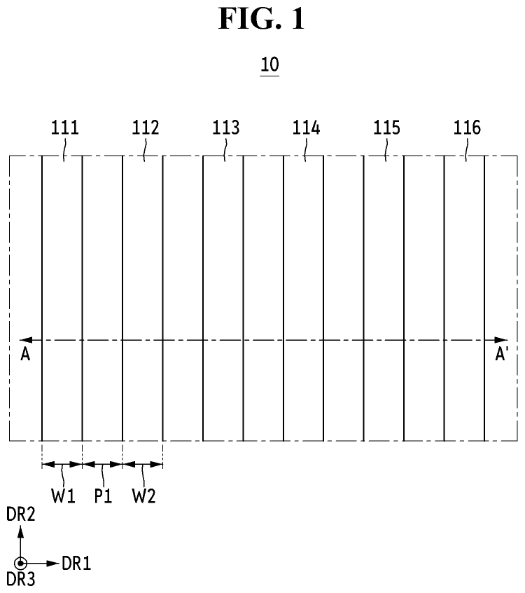

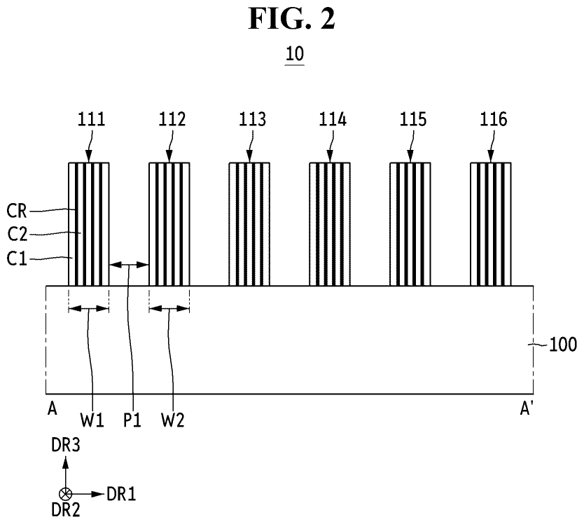

FIG. 1 is a layout diagram for explaining a semiconductor device, according to some exemplary embodiments of the present disclosure. FIG. 2 is a cross-sectional view taken along line A-A′ of FIG. 1, according to some exemplary embodiments of the present disclosure.

Referring to FIGS. 1 and 2, the semiconductor device 10, according to some exemplary embodiments of the present disclosure, may include a substrate 100 and first to sixth a plurality of wiring patterns (e.g., a first wiring pattern 111, a second wiring pattern 112, a third wiring pattern 113, a fourth wiring pattern 114, a fifth wiring pattern 115, and a sixth wiring pattern 116).

The substrate 100 may include a structure in which a base substrate and an epitaxial layer may be stacked. However, the present disclosure is not limited thereto. In some exemplary embodiments, the substrate 100 may be and/or may include a silicon (Si) substrate, a gallium arsenide (GaAs) substrate, a silicon germanium (SiGe) substrate, a ceramic substrate, a quartz substrate, or a glass substrate for displays. Alternatively, the substrate 100 may be and/or may include a semiconductor on insulator (SOI) substrate. In some exemplary embodiments, the substrate 100 may include a conductive pattern and an insulating layer. The conductive pattern may be and/or may include a metal wiring or contact, a gate electrode of a transistor, a source/drain of a transistor, or a diode. However, the present disclosure is not limited thereto.

As used herein, each of the first horizontal direction DR1 and the second horizontal direction DR2 may refer to a direction parallel to the upper surface of the substrate 100. The second horizontal direction DR2 may refer to a direction different from the first horizontal direction DR1. The vertical direction DR3 may refer to a direction perpendicular to both the first horizontal direction DR1 and the second horizontal direction DR2. That is, the vertical direction DR3 may refer to a direction perpendicular to the upper surface of the substrate 100.

Each wiring pattern of the plurality of first to sixth wiring patterns 111 to 116 may be disposed on the upper surface of the substrate 100. For example, each wiring pattern of the plurality of first to sixth wiring patterns 111 to 116 may extend in the second horizontal direction DR2. Although FIG. 1 depicts each wiring pattern of the plurality of first to sixth wiring patterns 111 to 116 arranged in parallel in the second horizontal direction DR2, the present disclosure is not limited thereto.

For example, the plurality of first to sixth wiring patterns 111 to 116 may be sequentially spaced apart in the first horizontal direction DR1 on the upper surface of the substrate 100. That is, the second wiring pattern 112 may be spaced apart from the first wiring pattern 111 in the first horizontal direction DR1. The third wiring pattern 113 may be spaced apart from the second wiring pattern 112 in the first horizontal direction DR1. The fourth wiring pattern 114 may be spaced apart from the third wiring pattern 113 in the first horizontal direction DR1. The fifth wiring pattern 115 may be spaced apart from the fourth wiring pattern 114 in the first horizontal direction DR1. The sixth wiring pattern 116 may be spaced apart from the fifth wiring pattern 115 in the first horizontal direction DR1.

In some embodiments, the bottom surface of each wiring pattern of the plurality of first to sixth wiring patterns 111 to 116 may be in contact with the upper surface of the substrate 100. For example, the bottom surface of each wiring pattern of the plurality of first to sixth wiring patterns 111 to 116 may be formed on the same plane. In some embodiments, the upper surface of each wiring pattern of the plurality of first to sixth wiring patterns 111 to 116 may be formed on the same plane. For example, the height of each wiring pattern of the plurality of first to sixth wiring patterns 111 to 116 in the vertical direction DR3 may be the same. That is, the height of the vertical direction DR3 from the bottom surface of each wiring pattern of the plurality of first to sixth wiring patterns 111 to 116 to the upper surface of each wiring pattern of the plurality of first to sixth wiring patterns 111 to 116 may be the same.

In some embodiments, each wiring pattern of the plurality of first to sixth wiring patterns 111 to 116 may be formed as a single layer. For example, each wiring pattern of the plurality of first to sixth wiring patterns 111 to 116 may include multiple crystals. The shape and arrangement of the multiple crystals included in each wiring pattern of the plurality of first to sixth wiring patterns 111 to 116 may be similar to each other. Consequently, the description may focus on the multiple crystals included in the first wiring pattern 111, and at least similar descriptions may apply to the crystals included in the remaining wiring patterns of the plurality of second to sixth wiring patterns 112 to 116. For example, the first wiring pattern 111 may include a first crystal C1 and a second crystal C2. The second crystal C2 may be arranged adjacent to the first crystal C1 in the first horizontal direction DR1. For example, the crystal orientation of each of the first crystal C1 and the second crystal C2 may be the vertical direction DR3 perpendicular to the upper surface of the substrate 100. That is, the first crystal C1 and the second crystal C2 may be formed to extend in the vertical direction DR3. As another example, the interface CR between the first crystal C1 and the second crystal C2 may extend in the vertical direction DR3. However, the present disclosure is not limited thereto. In some exemplary embodiments, the crystal orientation of each of the first crystal C1 and the second crystal C2 may be an acute angle to the upper surface of the substrate 100. In addition, the interface CR between the first crystal C1 and the second crystal C2 may be extended to have an acute angle with the upper surface of the substrate 100.

For example, each of the first crystal C1 and the second crystal C2 may extend in the vertical direction DR3 from the bottom surface of the first wiring pattern 111 to the upper surface of the first wiring pattern 111. As another example, the height of the second crystal C2 in the vertical direction DR3 may be the same as the height of the first crystal C1 in the vertical direction DR3. As used herein, the height of the first crystal C1 in the vertical direction DR3 may refer to the length of the vertical direction DR3 from the bottom surface of the first crystal C1 to the upper surface of the first crystal C1. Additionally, the height of the second crystal C2 in the vertical direction DR3 may refer to the length of the vertical direction DR3 from the bottom surface of the second crystal C2 to the upper surface of the second crystal C2.

In some embodiments, the upper surface of the second crystal C2 may be formed on the same plane as the upper surface of the first crystal C1. For example, the bottom surface of the second crystal C2 may be formed on the same plane as the bottom surface of the first crystal C1. As another example, the bottom surface of each of the first crystal C1 and the second crystal C2 may be in contact with the upper surface of the substrate 100. In some embodiments, the interface surface CR between the first crystal C1 and the second crystal C2 may be in contact with the upper surface of the substrate 100. Although, for the sake of convenience of description, FIG. 2 depicts each wiring pattern of the plurality of first to sixth wiring patterns 111 to 116 as including five (5) crystals, the present disclosure is not limited in this regard. For example, the number of crystals included in each wiring pattern of the plurality of first to sixth wiring patterns 111 to 116 may be smaller (e.g., less than five (5)) or may be larger (e.g., more than five (5)), without departing from the scope of the present disclosure. Alternatively or additionally, the crystal orientation of each of the multiple crystals included in each wiring pattern of the plurality of first to sixth wiring patterns 111 to 116 may vary from the vertical direction DR3.

In some embodiments, the width of each wiring pattern of the plurality of first to sixth wiring patterns 111 to 116 in the first horizontal direction DR1 may range from 1 nanometer (nm) to 20 nm. For example, the width W1 of the first wiring pattern 111 in the first horizontal direction DR1 may be substantially similar and/or the same as the width W2 of the second wiring pattern 112 in the first horizontal direction DR1. The widths of each wiring pattern of the plurality of first to sixth wiring patterns 111 to 116 in the first horizontal direction DR1 may be substantially similar and/or the same. However, the present disclosure is not limited thereto. For example, the widths of each wiring pattern of the plurality of first to sixth wiring patterns 111 to 116 in the first horizontal direction DR1 may be different.

In some embodiments, the distance P1 in the first horizontal direction DR1 between the first wiring pattern 111 and the second wiring pattern 112 may be substantially similar and/or equal to the distance in the first horizontal direction DR1 between the third wiring pattern 113 and the fourth wiring pattern 114 and the distance in the first horizontal direction DR1 between the fifth wiring pattern 115 and the sixth wiring pattern 116. For example, the distance in the first horizontal direction DR1 between each wiring pattern of the plurality of first to sixth wiring patterns 111 to 116 may be the same. However, the present disclosure is not limited in this regard. In some exemplary embodiments, the distance P1 in the first horizontal direction DR1 between the first wiring pattern 111 and the second wiring pattern 112 may be different from the distance in the first horizontal direction DR1 between the second wiring pattern 112 and the third wiring pattern 113 and the distance in the first horizontal direction DR1 between the fourth wiring pattern 114 and the fifth wiring pattern 115, respectively.

In some embodiments, the width of each wiring pattern of the plurality of first to sixth wiring patterns 111 to 116 in the first horizontal direction DR1 may be substantially similar and/or the same as the distance between each wiring pattern of the plurality of first to sixth wiring patterns 111 to 116 in the first horizontal direction DR1. For example, the distance P1 in the first horizontal direction DR1 between the first wiring pattern 111 and the second wiring pattern 112 may be equal to the width W1 of the first wiring pattern 111 in the first horizontal direction DR1 and the width W2 of the second wiring pattern 112 in the first horizontal direction DR1, respectively. However, the present disclosure is not limited thereto. In some exemplary embodiments, the distance P1 in the first horizontal direction DR1 between the first wiring pattern 111 and the second wiring pattern 112 may be different from each of the widths W1 of the first wiring pattern 111 in the first horizontal direction DR1 and W2 of the second wiring pattern 112 in the first horizontal direction DR1. For example, the height of each wiring pattern of the plurality of first to sixth wiring patterns 111 to 116 in the vertical direction DR3 may range from 1 nm to 100 nm.

In some embodiments, each wiring pattern of the plurality of first to sixth wiring patterns 111 to 116 may include the same material. For example, each wiring pattern of the plurality of first to sixth wiring patterns 111 to 116 may include a conductive material. In some embodiments, each wiring pattern of the plurality of first to sixth wiring patterns 111 to 116 may include, but not be limited to, at least one of iridium (Ir), platinum (Pt), rhodium (Rh), palladium (Pd), osmium (Os), niobium (Nb), ruthenium (Ru), copper (Cu), tungsten (W), molybdenum (Mo), cobalt (Co), titanium (Ti), tantalum (Ta), aluminum (Al), nickel (Ni), iron (Fe), or alloys thereof. For example, each wiring pattern of the plurality of first to sixth wiring patterns 111 to 116 may include an anisotropic conductor such as, but not limited to, platinum cobalt oxide (PtCoO₂), palladium cobalt oxide (PdCoO₂), palladium chromium oxide (PdCrO₂), chromium aluminum carbide (Cr₂AlC), vanadium aluminum carbide (V₂AlC), MXene, graphene, or doped forms thereof.

In the semiconductor device 10, according to some exemplary embodiments of the present disclosure, the crystal orientation of each of the multiple crystals (e.g., the first crystal C1 and the second crystal C2) included in each wiring pattern of the plurality of first to sixth wiring patterns 111 to 116 may be formed in a vertical direction DR3 perpendicular to the upper surface of the substrate 100. This may reduce the interfacial resistance between each wiring pattern of the plurality of first to sixth wiring patterns 111 to 116 and the substrate 100. That is, the interfacial resistance between the multiple crystals (e.g., the first crystal C1 and the second crystal C2) may be reduced by forming the crystal orientation of each crystal of the multiple crystals (e.g., the first crystal C1 and the second crystal C2) in the vertical direction DR3 perpendicular to the upper surface of the substrate 100, rather than forming the crystal orientation of each crystal of the multiple crystals (e.g., the first crystal C1 and the second crystal C2) parallel to and/or inclined to the upper surface of the substrate 100. As a result, the semiconductor device 10, according to some exemplary embodiments of the present disclosure, may have improved electrical characteristics, when compared to related semiconductor devices, by reducing the resistance of each wiring pattern of the plurality of first to sixth wiring patterns 111 to 116.

Hereinafter, a method for fabricating the semiconductor device 10, according to several exemplary embodiments of the present disclosure, is described with reference to FIGS. 1 to 9.

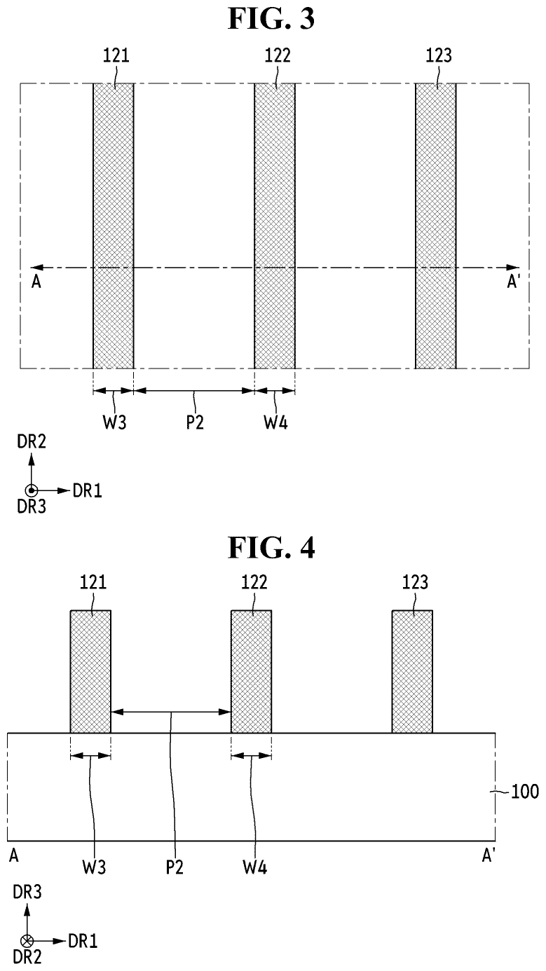

FIGS. 3 to 9 are intermediate stage diagrams for explaining the method for fabricating the semiconductor device 10 described with reference to FIGS. 1 and 2.

Referring to FIGS. 3 and 4, a plurality of sacrificial patterns (e.g., a first sacrificial pattern 121, a second sacrificial pattern 122, and a third sacrificial pattern 123) may be formed on the upper surface of the substrate 100. For example, each sacrificial pattern of the plurality of first to third sacrificial patterns 121 to 123 may extend in the second horizontal direction DR2. As another example, each sacrificial pattern of the plurality of first to third sacrificial patterns 121 to 123 may be sequentially spaced apart in the first horizontal direction DR1. That is, the second sacrificial pattern 122 may be spaced apart from the first sacrificial pattern 121 in the first horizontal direction DR1. The third sacrificial pattern 123 may be spaced apart from the second sacrificial pattern 122 in the first horizontal direction DR1. For example, the bottom surface of each sacrificial pattern of the plurality of first to third sacrificial patterns 121 to 123 may be in contact with the upper surface of the substrate 100. As another example, the upper surface of each sacrificial pattern of the plurality of first to third sacrificial patterns 121 to 123 may be formed on the same plane as each other. However, the present disclosure is not limited thereto.

For example, the width of each sacrificial pattern of the plurality of first to third sacrificial patterns 121 to 123 in the first horizontal direction DR1 may range from 1 nm to 20 nm. In some embodiments, the width W3 of the first sacrificial pattern 121 in the first horizontal direction DR1 may be substantially similar and/or the same as the width W4 of the second sacrificial pattern 122 in the first horizontal direction DR1. For example, the width of each sacrificial pattern of the plurality of first to third sacrificial patterns 121 to 123 in the first horizontal direction DR1 may be the same. However, the present disclosure is not limited thereto. For example, the width W3 of the first sacrificial pattern 121 in the first horizontal direction DR1 may be substantially similar and/or equal to the distance P1 in the first horizontal direction DR1 between the first wiring pattern 111 and the second wiring pattern 112.

In some embodiments, the distance P2 in the first horizontal direction DR1 between the first sacrificial pattern 121 and the second sacrificial pattern 122 may be greater than the width W3 of the first sacrificial pattern 121 in the first horizontal direction DR1 and the width W4 of the second sacrificial pattern 122 in the first horizontal direction DR1, respectively. For example, the distance P2 in the first horizontal direction DR1 between the first sacrificial pattern 121 and the second sacrificial pattern 122 may be three (3) times greater than the width W3 of the first sacrificial pattern 121 in the first horizontal direction DR1 (e.g., P2=3×W3) and the width W4 of the second sacrificial pattern 122 in the first horizontal direction DR1 (e.g., P2=3×W4), respectively. However, the present disclosure is not limited thereto.

In some embodiments, each sacrificial pattern of the plurality of first to third sacrificial patterns 121 to 123 may include a material having etching selectivity relative to each wiring material layer of a plurality of wiring material layers (e.g., a first wiring material layer 111M, a second wiring material layer 112M, and a third wiring material layer 113M). For example, each sacrificial pattern of the plurality of first to third sacrificial patterns 121 to 123 may include, but not be limited to, polysilicon (poly Si), silicon oxide (SiO₂), aluminum oxide (Al₂O₃), silicon nitride (Si₃N₄), metal oxide, or metal nitride. However, the present disclosure is not limited thereto.

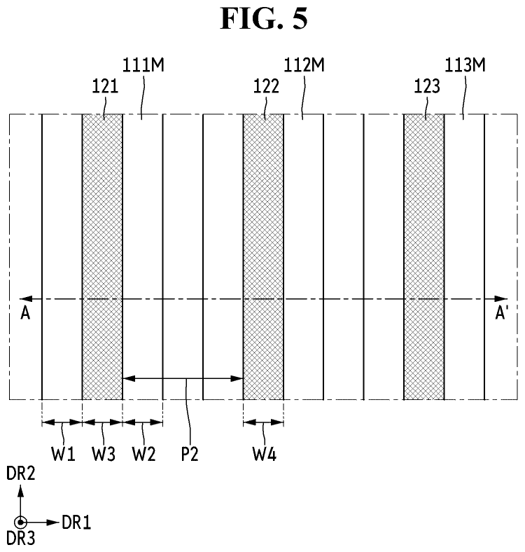

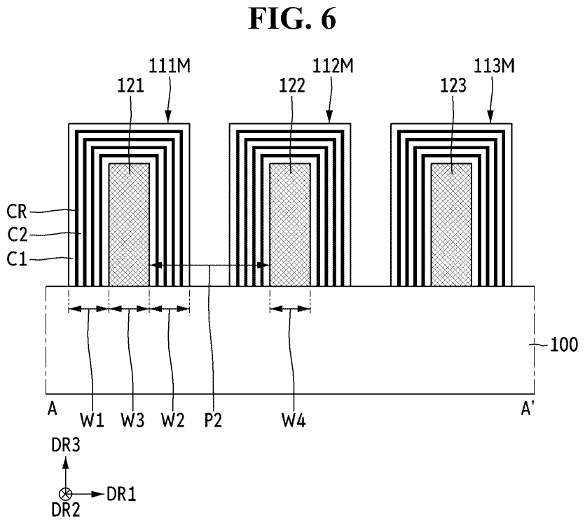

Referring to FIGS. 5 and 6, the plurality of first to third wiring material layers 111M to 113M may be formed on the sidewall and upper surface of each sacrificial pattern of the plurality of first to third sacrificial patterns 121 to 123, respectively. For example, the first wiring material layer 111M may be formed on the sidewall and upper surface of the first sacrificial pattern 121, the second wiring material layer 112M may be formed on the sidewall and upper surface of the second sacrificial pattern 122, and the third wiring material layer 113M may be formed on the sidewall and upper surface of the third sacrificial pattern 123. That is, the first wiring material layer 111M may cover the sidewall and upper surface of the first sacrificial pattern 121, the second wiring material layer 112M may cover the sidewall and upper surface of the second sacrificial pattern 122, and the third wiring material layer 113M may cover the sidewall and upper surface of the third sacrificial pattern 123.

In some embodiments, each wiring material layer of the plurality of first to third wiring material layers 111M to 113M may be selectively formed from the surface of each sacrificial pattern of the plurality of first to third sacrificial patterns 121 to 123. As a result, each wiring material layer of the plurality of first to third wiring material layers 111M to 113M may not be formed on a portion of the upper surface of the substrate 100 that is not adjacent to each sacrificial pattern of the plurality of first to third sacrificial patterns 121 to 123. That is, a portion of the upper surface of the substrate 100 may be exposed between each wiring material layer of the plurality of first to third wiring material layers 111M to 113M. For example, the second wiring material layer 112M may be spaced apart from the first wiring material layer 111M in the first horizontal direction DR1. As another example, the third wiring material layer 113M may be spaced apart from the second wiring material layer 112M in the first horizontal direction DR1.

In some embodiments, each wiring material layer of the plurality of first to third wiring material layers 111M to 113M may be formed with a substantially similar and/or the same thickness. For example, the width W1 of the first wiring material layer 111M in the first horizontal direction DR1, formed on a first sidewall of the first sacrificial pattern 121 may be equal to the width W2 of the first wiring material layer 111M in the first horizontal direction DR1, formed on a second sidewall of the first sacrificial pattern 121. As used herein, the second sidewall of the first sacrificial pattern 121 may refer to the sidewall that is opposite to the first sidewall of the first sacrificial pattern 121 in the first horizontal direction DR1. For example, the width W1 of the first wiring material layer 111M in the first horizontal direction DR1, formed on the first sidewall of the first sacrificial pattern 121 and the width W2 of the first wiring material layer 111M in the first horizontal direction DR, formed on the second sidewall of the first sacrificial pattern 121 may each be equal to the width W3 of the first sacrificial pattern 121 in the first horizontal direction DR1. However, the present disclosure is not limited thereto.

In some embodiments, each wiring material layer of the plurality of first to third wiring material layers 111M to 113M may be formed as a single layer. For example, each wiring material layer of the plurality of first to third wiring material layers 111M to 113M may include multiple crystals. The shapes and arrangements of the multiple crystals included in the plurality of first to third wiring material layers 111M to 113M may be similar to one another. Accordingly, the description may focus on the multiple crystals included in the first wiring material layer 111M, and at least similar descriptions may apply to the crystals included in the remaining wiring material layers of the plurality of second to third wiring material layers 112M to 113M. For example, the first wiring material layer 111M may include a first crystal C1 and a second crystal C2.

Each of the first crystal C1 and the second crystal C2 included in the first wiring material layer 111M may be formed parallel to both sidewalls of the first sacrificial pattern 121 in the first horizontal direction DR1. That is, the crystal orientation of each of the first crystal C1 and the second crystal C2 on both sidewalls of the first sacrificial pattern 121 in the first horizontal direction DR1 may be the vertical direction DR3 perpendicular to the upper surface of the substrate 100. Additionally, each of the first crystal C1 and the second crystal C2 may be formed parallel to the upper surface of the first sacrificial pattern 121. That is, on the upper surface of the first sacrificial pattern 121, the crystal orientation of each of the first crystal C1 and the second crystal C2 may be the first horizontal direction DR1 parallel to the upper surface of the substrate 100.

The interface surface CR between the first crystal C1 and the second crystal C2 may be formed parallel to both sidewalls of the first sacrificial pattern 121 in the first horizontal direction DR1. That is, the interface surface CR between the first crystal C1 and the second crystal C2 may extend in the vertical direction DR3 on both sidewalls of the first sacrificial pattern 121 in the first horizontal direction DR1. Additionally, the interface surface CR between the first crystal C1 and the second crystal C2 may be formed parallel to the upper surface of the first sacrificial pattern 121. That is, the interface surface CR between the first crystal C1 and the second crystal C2 on the upper surface of the first sacrificial pattern 121 may extend in the first horizontal direction DR1.

For example, each wiring material layer of the plurality of second to third wiring material layers 112M to 113M may have a substantially similar and/or the same shape as the first wiring material layer 111M. Accordingly, a description of the shape of each of the second and third wiring material layers 112M and 113M may be omitted for the sake of brevity. In some embodiments, each wiring material layer of the plurality of first to third wiring material layers 111M to 113M may include the same material as each other. For example, each wiring material layer of the plurality of first to third wiring material layers 111M to 113M may include a substantially similar and/or the same material as each wiring pattern of the plurality of first to sixth wiring patterns 111 to 116 described with reference to FIGS. 1 and 2.

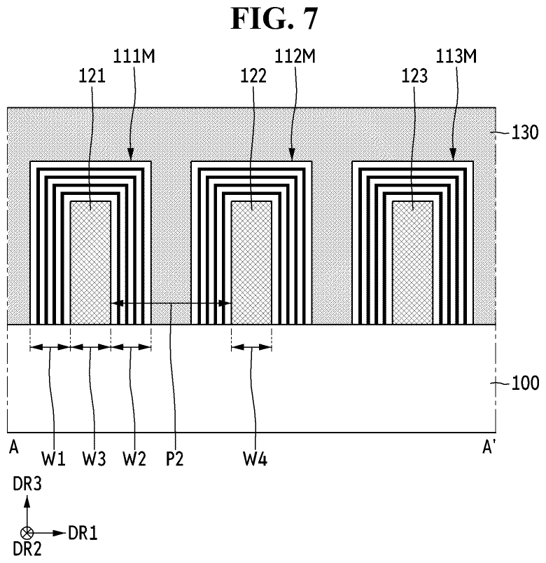

Referring to FIG. 7, a first protective layer 130 may be formed to cover each wiring material layer of the plurality of first to third wiring material layers 111M to 113M on the upper surface of the substrate 100. For example, the first protective layer 130 may fill the spaces between each wiring material layer of the plurality of first to third wiring material layers 111M to 113M. For example, the first protective layer 130 may be in contact with the upper surface of the substrate 100 between each wiring material layer of the plurality of first to third wiring material layers 111M to 113M. In some embodiments, the first protective layer 130 may include a material with etching selectivity relative to the plurality of first to third wiring material layers 111M to 113M. For example, the first protective layer 130 may include, but not be limited to, at least one of silicon oxide (SiO₂), silicon nitride (Si₃N₄), silicon oxynitride (Si₂N₂O), and low-k dielectric materials. In some exemplary embodiments, the first protective layer 130 may include, but not be limited to, spin-on hardmask (SOH).

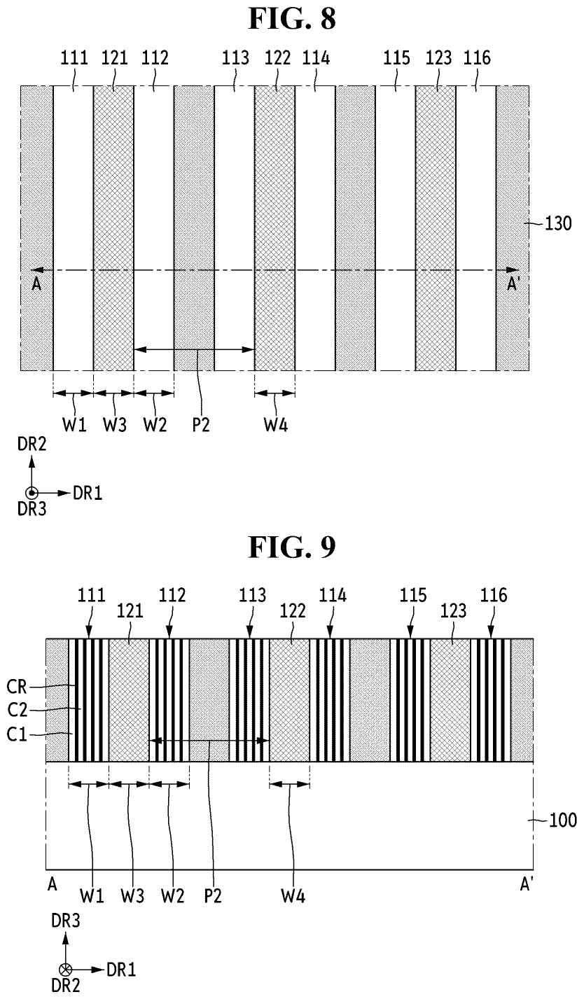

Referring to FIGS. 8 and 9, a planarization process (e.g., a chemical mechanical planarization (CMP) process) may be performed to etch away a portion of the first protective layer 130, and a portion of each wiring material layer of the plurality of first to third wiring material layers 111M to 113M. For example, the planarization process may continue until the upper surface of each sacrificial pattern of the plurality of first to third sacrificial patterns 121 to 123 is exposed. That is, after the planarization process is completed, the upper surface of each sacrificial pattern of the plurality of first to third sacrificial patterns 121 to 123 may be exposed.

In some embodiments, after the planarization process is completed, the remaining first wiring material layer 111M may be referred to as the first wiring pattern 111 and the second wiring pattern 112. Additionally, the remaining second wiring material layer 112M may be referred to as the third wiring pattern 113 and the fourth wiring pattern 114. Additionally, the remaining third wiring material layer 113M may be defined as the fifth wiring pattern 115 and the sixth wiring pattern 116. That is, by performing the planarization process, the first wiring material layer 111M may be separated into the first wiring pattern 111 and the second wiring pattern 112. Additionally, by performing the planarization process, the second wiring material layer 112M may be separated into the third wiring pattern 113 and the fourth wiring pattern 114. Furthermore, by performing the planarization process, the third wiring material layer 113M may be separated into the fifth wiring pattern 115 and the sixth wiring pattern 116.

Referring to FIGS. 1 and 2, the first protective layer 130, and each sacrificial pattern of the plurality of first to third sacrificial patterns 121 to 123 may be etched. The fabrication process described above with reference to FIGS. 3 to 9 may be used to fabricate the semiconductor device 10 described with reference to FIGS. 1 and 2.

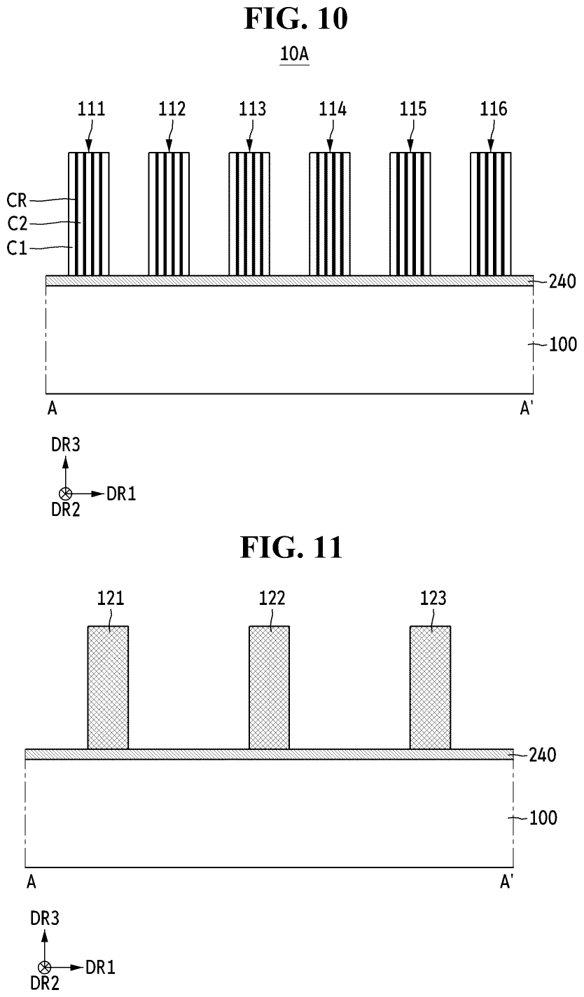

Hereinafter, a semiconductor device, according to additional or alternative exemplary embodiments of the present disclosure, is described with reference to FIG. 10. The semiconductor device 10A of FIG. 10 may include and/or may be similar in many respects to the semiconductor device 10 described above with reference to FIGS. 1 and 2, and may include additional features not mentioned above. Consequently, the description of the semiconductor device 10A may focus on the differences from the semiconductor device 10 described with reference to FIGS. 1 and 2, and repeated descriptions of the semiconductor device 10A described above with reference to FIGS. 1 and 2 may be omitted for the sake of brevity.

FIG. 10 is a cross-sectional view for explaining the semiconductor device 10A, according to several exemplary embodiments of the present disclosure.

Referring to FIG. 10, the semiconductor device 10A, according to some exemplary embodiments of the present disclosure, may include a liner layer 240 disposed on the upper surface of the substrate 100.

The liner layer 240 may be in contact with the upper surface of the substrate 100. For example, the liner layer 240 may be conformally formed. However, the present disclosure is not limited thereto. The liner layer 240 may be disposed between the bottom surface of each wiring pattern of the plurality of first to sixth wiring patterns 111 to 116 and the upper surface of the substrate 100. For example, the liner layer 240 may be in contact with the bottom surface of each wiring pattern of the plurality of first to sixth wiring patterns 111 to 116. As another example, the liner layer 240 may be in contact with the bottom surface of each of the first crystal C1 and second crystal C2. Additionally, the liner layer 240 may be in contact with the interface CR between the first crystal C1 and the second crystal C2.

In some exemplary embodiments, the liner layer 240 may include a self-assembled monolayer (SAM). For example, the self-assembled monolayer (SAM) may include, but not be limited to, at least one of octadecyltrimethoxysilane (ODS), octadecylphosphonic acid (ODPA), or octadecyltrichlorosilane (ODTS). In some exemplary embodiments, the liner layer 240 may include, but not be limited to, at least one of bis(N,N-dimethylamino)dimethylsilane (DMADMS) or (N,N-dimethylamino)trimethylsilane (DMATMS). In some embodiments, the liner layer 240 may include, but not be limited to, at least one of a polymer and a polymer brush (polymer and end-functionalized polymer). For example, the polymer and polymer brush (polymer and end-functionalized polymer) may include, but not be limited to, at least one of polymers (e.g., poly(vinyl pyrrolidone), polymethyl methacrylate (PMMA), polystyrene, polyimide) and/or end-functionalized forms such as, but not limited to, materials from the hydroxyl group (—OH), the chloro group (—Cl), the carboxyl group (—COOH), the bromo group (—Br), the fluoro group (—F), or the methoxy group (—OCH₃). In some exemplary embodiments, the liner layer 240 may include, but not be limited to, at least one of aluminum (Al), titanium (Ti), chromium (Cr), manganese (Mn), iron (Fe), cobalt (Co), nickel (Ni), copper (Cu), zinc (Zn), zirconium (Zr), molybdenum (Mo), niobium (Nb), ruthenium (Ru), palladium (Pd), cadmium (Cd), indium (In), gold (Au), iridium (Ir), platinum (Pt), osmium (Os), tungsten (W), tantalum (Ta), hafnium (Hf), and their alloys, and metal nitrides, metal carbides, metal borides, and metal oxides containing these elements.

Hereinafter, referring to FIGS. 10 and 11, a method for fabricating the semiconductor device 10A, according to additional or alternative exemplary embodiments of the present disclosure, is described. The method for fabricating the semiconductor device 10A may include and/or may be similar in many respects to the method for fabricating the semiconductor device 10 described above with reference to FIGS. 1 to 9, and may include additional features not mentioned above. Consequently, the description of the method for fabricating the semiconductor device 10A may focus on differences from the method for fabricating the semiconductor device 10 described with reference to FIGS. 1 to 9, and repeated descriptions of the method for fabricating the semiconductor device 10 described above with reference to FIGS. 1 to 9 may be omitted for the sake of brevity.

FIG. 11 is an intermediate stage diagram for explaining the method for fabricating the semiconductor device 10A described with reference to FIG. 10.

Referring to FIG. 11, a liner layer 240 may be formed on the upper surface of the substrate 100. The liner layer 240 may be in contact with the upper surface of the substrate 100. For example, the liner layer 240 may be formed conformally. Subsequently, a plurality of first to third sacrificial patterns 121 to 123 may be formed on the upper surface of the liner layer 240. The bottom surface of each sacrificial pattern of the plurality of first to third sacrificial patterns 121 to 123 may be in contact with the upper surface of the liner layer 240. The plurality of first to third sacrificial patterns 121 to 123 may each extend in the second horizontal direction DR2. For example, each sacrificial pattern of the plurality of first to third sacrificial patterns 121 to 123 may be sequentially spaced apart in the first horizontal direction DR1. Subsequently, the fabrication process described with reference to FIGS. 5 to 9 may be performed.

Referring to FIG. 10, the first protective layer 130 and each sacrificial pattern of the plurality of first to third sacrificial patterns 121 to 123 formed on the upper surface of the liner layer 240 may be etched. The fabrication process described above with reference to FIGS. 10 and 11 may be used to fabricate the semiconductor device 10A shown in FIG. 10.

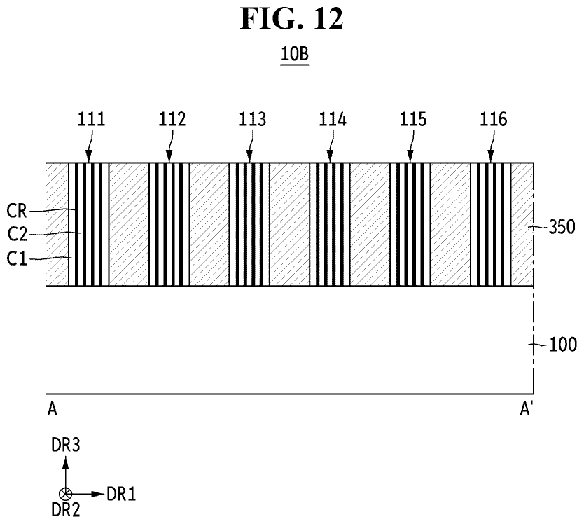

Hereinafter, a semiconductor device, according to several additional or alternative exemplary embodiments of the present disclosure, is described with reference to FIG. 12. The semiconductor device 10B of FIG. 12 may include and/or may be similar in many respects to the semiconductor device 10 described above with reference to FIGS. 1 and 2, and may include additional features not mentioned above. Consequently, the description of the semiconductor device 10B may focus on the differences from the semiconductor device 10 described with reference to FIGS. 1 and 2, and repeated descriptions of the semiconductor device 10B described above with reference to FIGS. 1 and 2 may be omitted for the sake of brevity.

FIG. 12 is a cross-sectional view for explaining the semiconductor device 10B, according to several exemplary embodiments of the present disclosure.

Referring to FIG. 12, the semiconductor device 10B, according to some exemplary embodiments of the present disclosure, may include an interlayer insulating layer 350 disposed on the upper surface of the substrate 100.

The interlayer insulating layer 350 may surround the sidewalls of each wiring pattern of the plurality of first to sixth wiring patterns 111 to 116 on the upper surface of the substrate 100. For example, the interlayer insulating layer 350 may be in contact with the upper surface of the substrate 100. As another example, the upper surface of the interlayer insulating layer 350 may be formed on the same plane as the upper surface of each wiring pattern of the plurality of first to sixth wiring patterns 111 to 116. However, the present disclosure is not limited to these examples.

In some embodiments, the interlayer insulating layer 350 may include, but not be limited to, at least one of silicon oxide (SiO₂), silicon nitride (Si₃N₄), silicon oxynitride (Si₂N₂O), or low-k dielectric materials. The low-k dielectric materials may include, but not be limited to, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylcyCloTetraSiloxane (OMCTS), HexaMethylDiSiloxane (HMDS), TriMethylSilyl Borate (TMSB), DiAcetoxyDitertiaryButoxySiloxane (DADBS), TriMethylSilyl Phosphate (TMSP), PolyTetraFluoroEthylene (PTFE), Tonen SilaZen (TOSZ), Fluoride Silicate Glass (FSG), polyimide nanofoams such as, but not limited to, polypropylene oxide (C₃H₆O), Carbon Doped silicon Oxide (CDO), Organo Silicate Glass (OSG), Dow Chemical SiLK™, Amorphous Fluorinated Carbon, silica aerogels, silica xerogels, mesoporous silica, or combinations thereof. However, the present disclosure is not limited thereto.

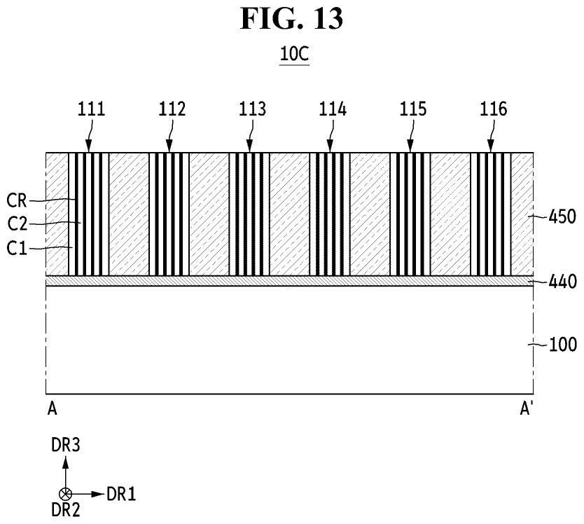

Hereinafter, a semiconductor device, according to additional or alternative exemplary embodiments of the present disclosure, is described with reference to FIG. 13. The semiconductor device 10C of FIG. 13 may include and/or may be similar in many respects to the semiconductor device 10 described above with reference to FIGS. 1 and 2, and may include additional features not mentioned above. Consequently, the description of the semiconductor device 10C may focus on the differences from the semiconductor device 10 described with reference to FIGS. 1 and 2, and repeated descriptions of the semiconductor device 10C described above with reference to FIGS. 1 and 2 may be omitted for the sake of brevity.

FIG. 13 is a cross-sectional view for explaining the semiconductor device 10C, according to several exemplary embodiments of the present disclosure.

Referring to FIG. 13, the semiconductor device 10C, according to several embodiments of the present disclosure, may include a liner layer 440 and an interlayer insulating layer 450 disposed on the upper surface of the substrate 100.

The liner layer 440 may be in contact with the upper surface of the substrate 100. For example, the liner layer 440 may be formed conformally. However, the present disclosure is not limited thereto. The liner layer 440 may be disposed between the bottom surface of each wiring pattern of the plurality of first to sixth wiring patterns 111 to 116 and the upper surface of the substrate 100. For example, the liner layer 440 may be in contact with the bottom surface of each wiring pattern of the plurality of first to sixth wiring patterns 111 to 116. As another example, the liner layer 440 may be in contact with the bottom surface of each of the first crystal C1 and second crystal C2. Additionally, the liner layer 440 may be in contact with the interface CR between the first crystal C1 and the second crystal C2. For example, the liner layer 440 may include a substantially similar and/or the same material as the liner layer 240 described with reference to FIG. 10.

In some embodiments, the interlayer insulating layer 450 may surround the sidewalls of each wiring pattern of the plurality of first to sixth wiring patterns 111 to 116 on the upper surface of the liner layer 440. For example, the interlayer insulating layer 450 may be in contact with the upper surface of the liner layer 440. As another example, the upper surface of the interlayer insulating layer 450 may be formed on the same plane as the upper surface of each wiring pattern of the plurality of first to sixth wiring patterns 111 to 116. However, the present disclosure is not limited in this regard. The interlayer insulating layer 450 may include a substantially similar and/or the same material as the interlayer insulating layer 350 described with reference to FIG. 12.

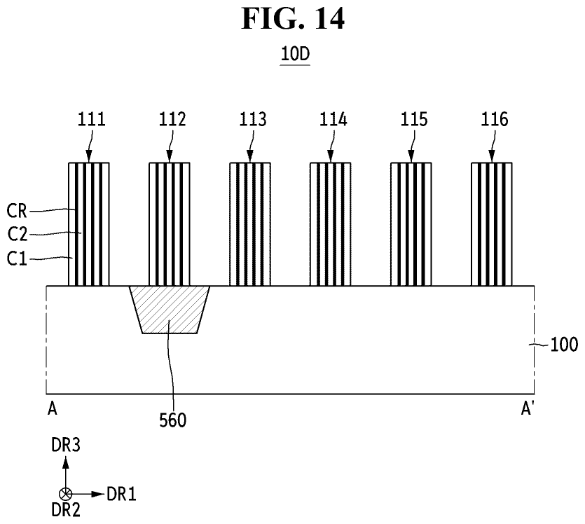

Hereinafter, a semiconductor device, according to several additional or alternative exemplary embodiments of the present disclosure, is described with reference to FIG. 14. The semiconductor device 10D of FIG. 14 may include and/or may be similar in many respects to the semiconductor device 10 described above with reference to FIGS. 1 and 2, and may include additional features not mentioned above. Consequently, the description of the semiconductor device 10D may focus on the differences from the semiconductor device 10 described with reference to FIGS. 1 and 2, and repeated descriptions of the semiconductor device 10D described above with reference to FIGS. 1 and 2 may be omitted for the sake of brevity.

FIG. 14 is a cross-sectional view for explaining the semiconductor device 10D, according to several exemplary embodiments of the present disclosure.

Referring to FIG. 14, the semiconductor device 10D, according to some exemplary embodiments of the present disclosure, may include a via 560 disposed inside the substrate 100.

In some embodiments, the via 560 may be positioned to be recessed toward the inside of the substrate 100 from the upper surface of the substrate 100. For example, the upper surface of the via 560 may be formed on the same plane as the upper surface of the substrate 100. The via 560 may be disposed beneath any one of the plurality of first to sixth wiring patterns 111 to 116. For example, the via 560 may be placed beneath the second wiring pattern 112. The via 560 may be electrically connected to the second wiring pattern 112. For example, the upper surface of the via 560 may be in contact with the second wiring pattern 112. In some embodiments, the via 560 may include a conductive material.

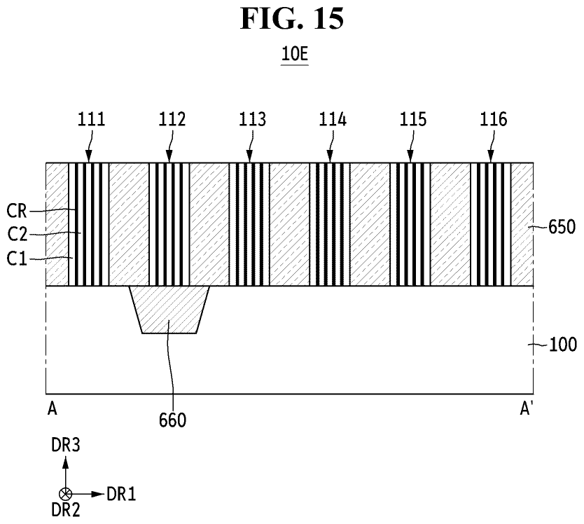

Hereinafter, a semiconductor device, according to several additional or alternative exemplary embodiments of the present disclosure, is described with reference to FIG. 15. The semiconductor device 10E of FIG. 15 may include and/or may be similar in many respects to the semiconductor device 10 described above with reference to FIGS. 1 and 2, and may include additional features not mentioned above. Consequently, the description of the semiconductor device 10E may focus on the differences from the semiconductor device 10 described with reference to FIGS. 1 and 2, and repeated descriptions of the semiconductor device 10E described above with reference to FIGS. 1 and 2 may be omitted for the sake of brevity.

FIG. 15 is a cross-sectional view for explaining the semiconductor device 10E, according to several exemplary embodiments of the present disclosure.

Referring to FIG. 15, in the semiconductor device 10E, according to several exemplary embodiments of the present disclosure, a via 660 may be disposed inside the substrate 100, and an interlayer insulating layer 650 may be disposed on the upper surface of each of the via 660 and the substrate 100.

In some embodiments, the via 660 may be disposed inside the substrate 100 in a substantially similar and/or the same manner as the via 560 described with reference to FIG. 14. The via 660 may include a conductive material. In some embodiments, the interlayer insulating layer 650 may surround the sidewalls of each wiring pattern of the plurality of first to sixth wiring patterns 111 to 116 on the upper surface of each of the substrate 100 and via 660. For example, the interlayer insulating layer 650 may be in contact with both the upper surfaces of both the substrate 100 and the via 660. As another example, the upper surface of the interlayer insulating layer 650 may be formed on the same plane as the upper surface of each wiring pattern of the plurality of first to sixth wiring patterns 111 to 116. However, the present disclosure is not limited in this regard. For example, the interlayer insulating layer 650 may include a substantially similar and/or the same material as the interlayer insulating layer 350 described with reference to FIG. 12.

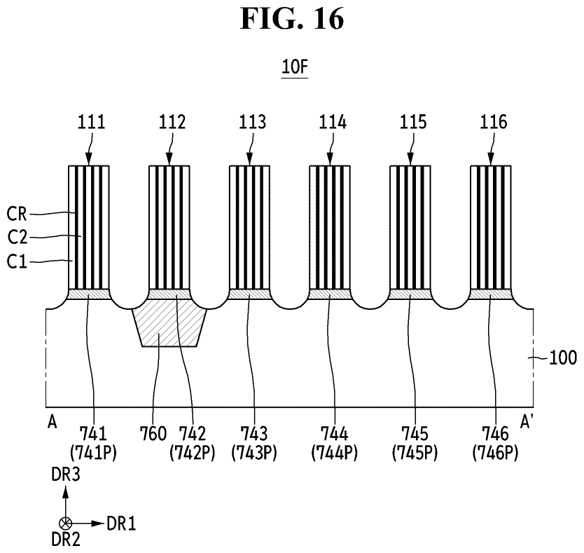

Hereinafter, a semiconductor device, according to several additional or alternative exemplary embodiments of the present disclosure, is described with reference to FIG. 16. The semiconductor device 10F of FIG. 16 may include and/or may be similar in many respects to the semiconductor device 10 described above with reference to FIGS. 1 and 2, and may include additional features not mentioned above. Consequently, the description of the semiconductor device 10F may focus on the differences from the semiconductor device 10 described with reference to FIGS. 1 and 2, and repeated descriptions of the semiconductor device 10F described above with reference to FIGS. 1 and 2 may be omitted for the sake of brevity.

FIG. 16 is a cross-sectional view for explaining the semiconductor device 10F, according to some exemplary embodiments of the present disclosure.

Referring to FIG. 16, the semiconductor device 10F, according to several exemplary embodiments of the present disclosure, may include a via 760 disposed inside a substrate 100, and a plurality of liner layers (e.g., a first liner layer 741, a second liner layer 742, a third liner layer 743, a fourth liner layer 744, a fifth liner layer 745, and a sixth liner layer 746) may be disposed on the upper surfaces of the via 760 and the substrate 100, respectively.

In some embodiments, the via 760 may be disposed to be recessed toward the inside of the substrate 100 from the upper surface of the substrate 100. For example, the uppermost surface of the via 760 may be formed on the same plane as the uppermost surface of the substrate 100. The via 760 may be disposed beneath any one of the plurality of first to sixth wiring patterns 111 to 116. For example, the via 760 may be disposed beneath the second wiring pattern 112. The via 760 may be electrically connected to the second wiring pattern 112. In some embodiments, the via 760 may include a conductive material.

Each liner layer of the plurality of first to sixth liner layers 741 to 746 may include a corresponding liner pattern from a plurality of liner patterns (e.g., a first liner pattern 741P, a second liner pattern 742P, a third liner pattern 743P, a fourth liner pattern 744P, a fifth liner pattern 745P, and a sixth liner pattern 746P). For example, the first liner pattern 741P may be disposed between the upper surface of the substrate 100 and the bottom surface of the first wiring pattern 111. The first liner pattern 741P may be in contact with each of the upper surface of the substrate 100 and the bottom surface of the first wiring pattern 111. As another example, the second liner pattern 742P may be disposed between the upper surface of the via 760 and the bottom surface of the second wiring pattern 112. The second liner pattern 742P may be spaced apart from the first liner pattern 741P in the first horizontal direction DR1. The second liner pattern 742P may be in contact with each of the upper surface of the via 760 and the bottom surface of the second wiring pattern 112.

In some embodiments, the upper surface of the via 760 may include a first upper surface and a second upper surface formed on either side of the first upper surface in the first horizontal direction. The first upper surface of the via 760 may overlap with the second wiring pattern 112 in the vertical direction DR3, while the second upper surface of the via 760 may not overlap with the second wiring pattern 112 in the vertical direction DR3. For example, the first upper surface of the via 760 may be in contact with the bottom surface of the second liner pattern 742P. As another example, the second upper surface of the via 760 may be formed concave toward the via 760. That is, the second upper surface of the via 760 may be formed lower than the uppermost surface of the substrate 100. For example, between each wiring pattern of the plurality of first to sixth wiring patterns 111 to 116, the upper surface of the substrate 100 may be formed concave toward the inside of the substrate 100.

In some embodiments, the third liner pattern 743P may be disposed between the upper surface of the substrate 100 and the bottom surface of the third wiring pattern 113. The third liner pattern 743P may be spaced apart from the second liner pattern 742P in the first horizontal direction DR1. The third liner pattern 743P may be in contact with each of the upper surface of the substrate 100 and the bottom surface of the third wiring pattern 113. The fourth liner pattern 744P may be disposed between the upper surface of the substrate 100 and the bottom surface of the fourth wiring pattern 114. The fourth liner pattern 744P may be spaced apart from the third liner pattern 743P in the first horizontal direction DR1. The fourth liner pattern 744P may be in contact with each of the upper surface of the substrate 100 and the bottom surface of the fourth wiring pattern 114. The fifth liner pattern 745P may be disposed between the upper surface of the substrate 100 and the bottom surface of the fifth wiring pattern 115. The fifth liner pattern 745P may be spaced apart from the fourth liner pattern 744P in the first horizontal direction DR1. The fifth liner pattern 745P may be in contact with each of the upper surface of the substrate 100 and the bottom surface of the fifth wiring pattern 115. The sixth liner pattern 746P may be disposed between the upper surface of the substrate 100 and the bottom surface of the sixth wiring pattern 116. The sixth liner pattern 746P may be spaced apart from the fifth liner pattern 745P in the first horizontal direction DR1. The sixth liner pattern 746P may be in contact with each of the upper surface of the substrate 100 and the bottom surface of the sixth wiring pattern 116. The plurality of first to sixth liner layers 741 to 746 may include a substantially similar and/or the same material as the liner layer 440 described with reference to FIG. 10.

Hereinafter, a method for fabricating the semiconductor device 10F, according to several additional or alternative exemplary embodiments of the present disclosure is be described with reference to FIGS. 16 to 21. The method for fabricating the semiconductor device 10F may include and/or may be similar in many respects to the method for fabricating the semiconductor device 10 described above with reference to FIGS. 1 to 9, and may include additional features not mentioned above. Consequently, the description of the method for fabricating the semiconductor device 10F may focus on the differences from the method for fabricating the semiconductor device 10 described with reference to FIGS. 1 to 9, and repeated descriptions of the method for fabricating the semiconductor device 10 described above with reference to FIGS. 1 to 9 may be omitted for the sake of brevity.

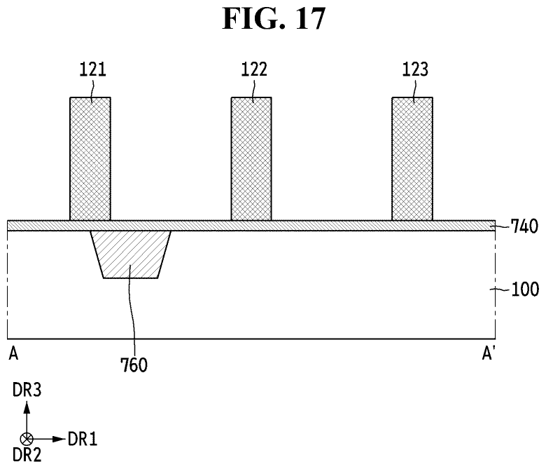

FIGS. 17 to 21 are intermediate stage drawings for explaining the method for fabricating the semiconductor device 10F described with reference to FIG. 16.

Referring to FIG. 17, a via 760 may be formed inside the substrate 100. For example, the upper surface of the via 760 may be exposed on the upper surface of the substrate 100. Subsequently, a liner layer 740 may be formed on the upper surface of each of the via 760 and the substrate 100. The liner layer 740 may be in contact with each of the upper surfaces of the via 760 and the substrate 100. For example, the liner layer 740 may be formed conformally. Subsequently, the plurality of first to third sacrificial patterns 121 to 123 may be formed on the upper surface of the liner layer 740. The bottom surface of each sacrificial pattern of the plurality of first to third sacrificial patterns 121 to 123 may be in contact with the upper surface of the liner layer 740.

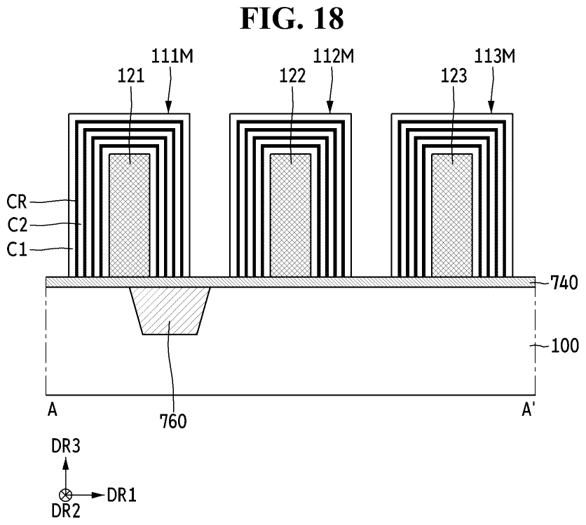

Referring to FIG. 18, each wiring material layer of the plurality of first to third wiring material layers 111M to 113M may be formed on the sidewall and upper surface of each sacrificial pattern of the plurality of first to third sacrificial patterns 121 to 123. For example, each wiring material layer of the plurality of first to third wiring material layers 111M to 113M may be selectively formed on the surface of each sacrificial pattern of the plurality of first to third sacrificial patterns 121 to 123. As a result, each wiring material layer of the plurality of first to third wiring material layers 111M to 113M may not be formed on a portion of the upper surface of the liner layer 740 that is not adjacent to each sacrificial pattern of the plurality of first to third sacrificial patterns 121 to 123. That is, a portion of the upper surface of the liner layer 740 may be exposed between each wiring material layer of the plurality of first to third wiring material layers 111M to 113M.

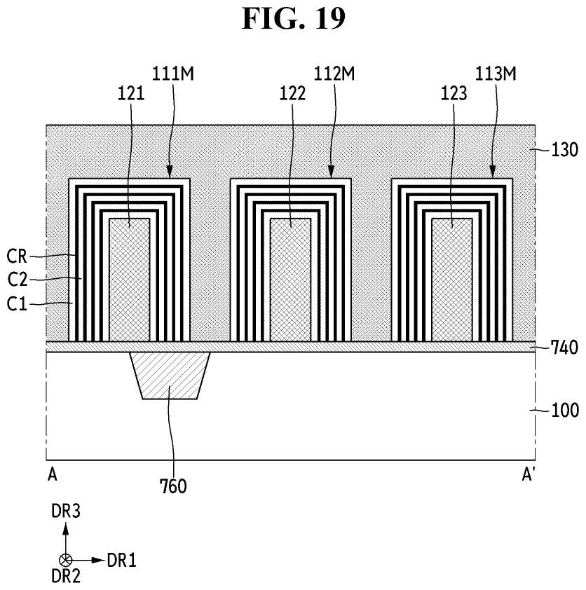

Referring to FIG. 19, a first protective layer 130 may be formed to cover each wiring material layer of the plurality of first to third wiring material layers 111M to 113M on the upper surface of the liner layer 740. For example, the first protective layer 130 may fill the space between each wiring material layer of the plurality of first to third wiring material layers 111M to 113M. As another example, the first protective layer 130 may be in contact with the upper surface of the liner layer 740 between each wiring material layer of the plurality of first to third wiring material layers 111M to 113M.

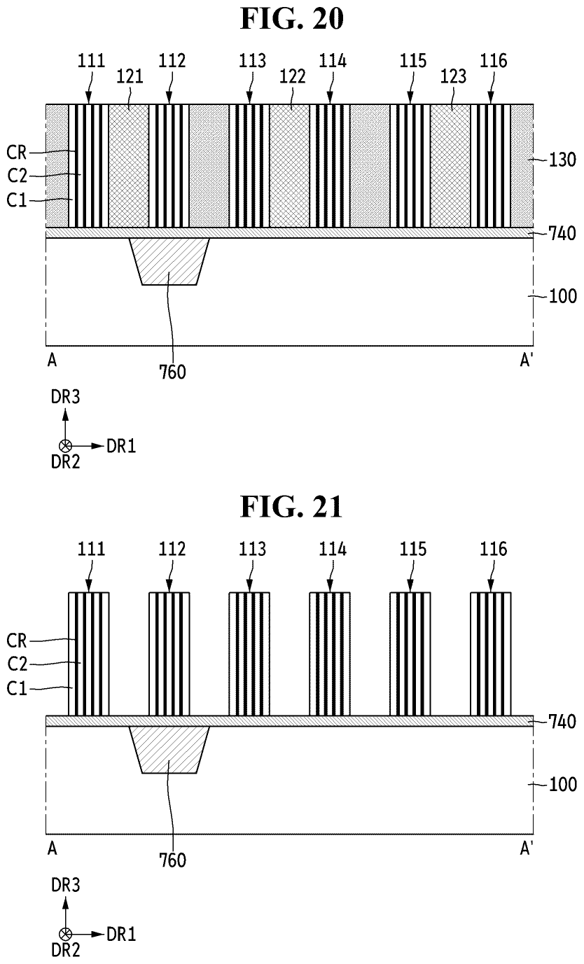

Referring to FIG. 20, a planarization process (e.g., a CMP process) may be performed to etch away a portion of the first protective layer 130 and a portion of each wiring material layer of the plurality of first to third wiring material layers 111M to 113M. For example, the planarization process may continue until the upper surfaces of each sacrificial pattern of the plurality of first to third sacrificial patterns 121 to 123 are exposed. That is, after the planarization process is completed, the upper surface of each sacrificial pattern of the plurality of first to third sacrificial patterns 121 to 123 may be exposed.

In some embodiments, after the planarization process is completed, the remaining first wiring material layer 111M may be referred to as the first wiring pattern 111 and the second wiring pattern 112. Additionally, the remaining second wiring material layer 112M may be referred to as the third wiring pattern 113 and the fourth wiring pattern 114. Additionally, the remaining third wiring material layer 113M may be referred to as the fifth wiring pattern 115 and the sixth wiring pattern 116. That is, by performing the planarization process, the first wiring material layer 111M may be separated into the first wiring pattern 111 and the second wiring pattern 112. Additionally, by performing the planarization process, the second wiring material layer 112M may be separated into the third wiring pattern 113 and the fourth wiring pattern 114. Furthermore, by performing the planarization process, the third wiring material layer 113M may be separated into the fifth wiring pattern 115 and the sixth wiring pattern 116.

Referring to FIG. 21, the first protective layer 130, and each sacrificial pattern of the plurality of first to third sacrificial patterns 121 to 123 may be etched.

Referring to FIG. 16, a portion of the liner layer 740 that is exposed between each wiring pattern of the plurality of first to sixth wiring patterns 111 to 116 may be etched. For example, while the portion of the liner layer 740 is being etched, portions of the substrate 100 and the via 760 may also be etched. Through this etching process, the liner layer 740 may be separated into the plurality of first to sixth liner patterns 741 to 746. For example, each liner pattern of the plurality of first to sixth liner patterns 741P to 746P may overlap with each wiring pattern of the plurality of first to sixth wiring patterns 111 to 116 in the vertical direction DR3. The fabrication process described above with reference to FIGS. 16 to 21 may be used to fabricate the semiconductor device 10F shown in FIG. 16.

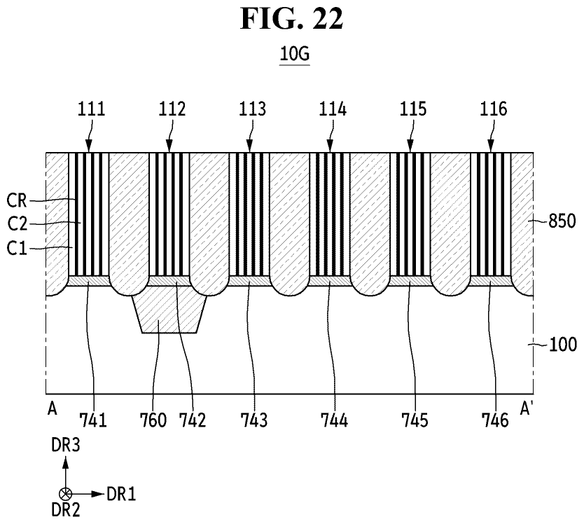

Hereinafter, a semiconductor device, according to several additional or alternative exemplary embodiments of the present disclosure, is described with reference to FIG. 22. The semiconductor device 10G of FIG. 22 may include and/or may be similar in many respects to the semiconductor device 10F described above with reference to FIG. 16, and may include additional features not mentioned above. Consequently, the description of the semiconductor device 10G may focus on the differences from the semiconductor device 10F described with reference to FIG. 16, and repeated descriptions of the semiconductor device 10G described above with reference to FIG. 16 may be omitted for the sake of brevity.

FIG. 22 is a cross-sectional view for explaining the semiconductor device 10G, according to several exemplary embodiments of the present disclosure.

Referring to FIG. 22, in the semiconductor device 10G, according to several exemplary embodiments of the present disclosure, an interlayer insulating layer 850 may be disposed on the upper surfaces of the via 760 and the substrate 100.

For example, the interlayer insulating layer 850 may surround the sidewalls of each wiring pattern of the plurality of first to sixth wiring patterns 111 to 116 on the upper surface of each of the substrate 100 and the via 760. In addition, the interlayer insulating layer 850 may surround the sidewalls of each liner pattern of the plurality of first to sixth liner patterns 741P to 746P on the upper surface of each of the substrate 100 and the via 760. For example, the interlayer insulating layer 850 may be in contact with the upper surface of each of the substrate 100 and the via 760. For example, the interlayer insulating layer 850 may be in contact with the sidewalls of each liner pattern of the plurality of first to sixth liner patterns 741P to 746P. For example, the upper surface of the interlayer insulating layer 850 may be formed on the same plane as the upper surface of each wiring pattern of the plurality of first to sixth wiring patterns 111 to 116. However, the present disclosure is not limited thereto. The interlayer insulating layer 850 may include a substantially similar and/or the same material as the interlayer insulating layer 350 described with reference to FIG. 12.

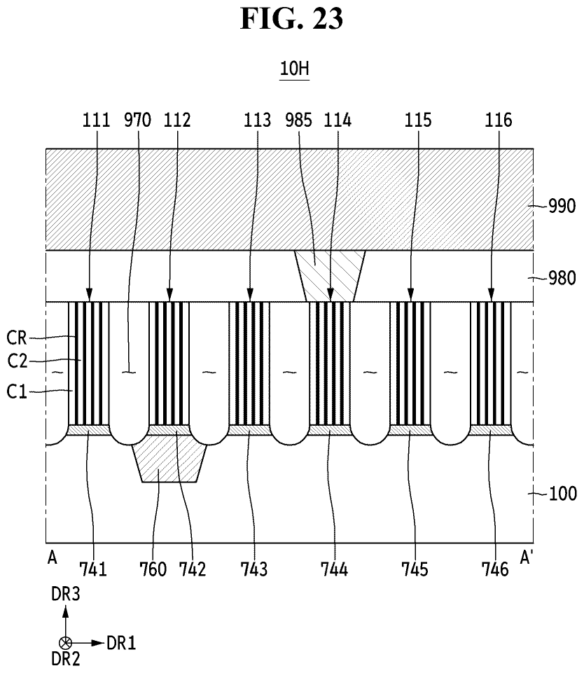

Hereinafter, a semiconductor device, according to several additional or alternative exemplary embodiments of the present disclosure, is described with reference to FIG. 23. The semiconductor device 10H of FIG. 23 may include and/or may be similar in many respects to the semiconductor device 10F described above with reference to FIG. 16, and may include additional features not mentioned above. Consequently, the description may focus on the differences from the semiconductor device 10H described with reference to FIG. 16, and repeated descriptions of the semiconductor device 10H described above with reference to FIG. 16 may be omitted for the sake of brevity.

FIG. 23 is a cross-sectional view for explaining the semiconductor device 10H, according to several exemplary embodiments of the present disclosure.

Referring to FIG. 23, in the semiconductor device 10H, according to several exemplary embodiments of the present disclosure, an air gap 970 may be formed between the plurality of first to sixth wiring patterns 111 to 116.

For example, an upper interlayer insulating layer 980 may be disposed on the upper surface of each wiring pattern of the plurality of first to sixth wiring patterns 111 to 116. The upper interlayer insulating layer 980 may be in contact with the upper surface of each wiring pattern of the plurality of first to sixth wiring patterns 111 to 116. For example, the upper interlayer insulating layer 980 may include, but not be limited to, at least one or more of silicon oxide (SiO₂), silicon nitride (Si₃N₄), silicon oxynitride (Si₂N₂O), or low-k dielectric materials. As used herein, the air gap 970 may be referred to as the space formed between the plurality of first to sixth wiring patterns 111 to 116, between the upper surface of each of the vias 760 and the substrate 100, and the bottom surface of the upper interlayer insulating layer 980. For example, the air gap 970 may expose a portion of the upper surface of the substrate 100, a portion of the upper surface of the via 760, and a portion of the bottom surface of the upper interlayer insulating layer 980.

In some embodiments, the upper via 985 may be disposed inside the upper interlayer insulating layer 980. The upper via 985 may be disposed above any one of the plurality of first to sixth wiring patterns 111 to 116. For example, the via 560 may be disposed beneath the second wiring pattern 112. The upper via 985 may be electrically connected to the fourth wiring pattern 114. For example, the bottom surface of the upper via 985 may be in contact with the fourth wiring pattern 114. The upper via 985 may include a conductive material. For example, the upper wiring pattern 990 may be disposed on the upper surface of the upper interlayer insulating layer 980. The upper wiring pattern 990 may be electrically connected to the upper via 985. The upper wiring pattern 990 may include a conductive material.

Hereinafter, a method for fabricating the semiconductor device 10H, according to several additional or alternative exemplary embodiments of the present disclosure, is described with reference to FIGS. 23 to 25. The method for fabricating the semiconductor device 10H may include and/or may be similar in many respects to the method for fabricating the semiconductor device 10F described above with reference to FIGS. 16 to 21, and may include additional features not mentioned above. Consequently, the description of the method for fabricating the semiconductor device 10H may focus on the differences from the method for fabricating the semiconductor device 10F described with reference to FIGS. 16 to 21, and repeated descriptions of the method for fabricating the semiconductor device 10F described above with reference to FIGS. 16 to 21 may be omitted for the sake of brevity.

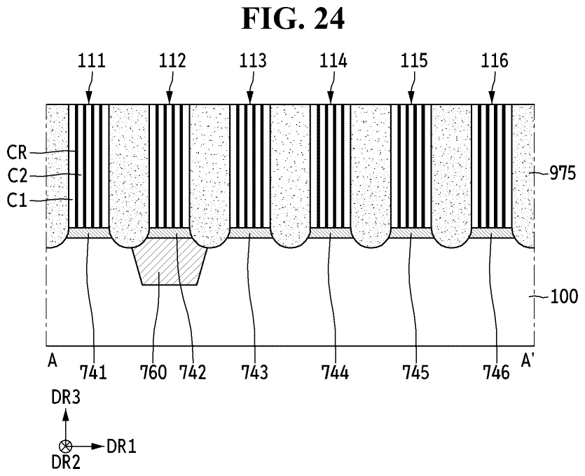

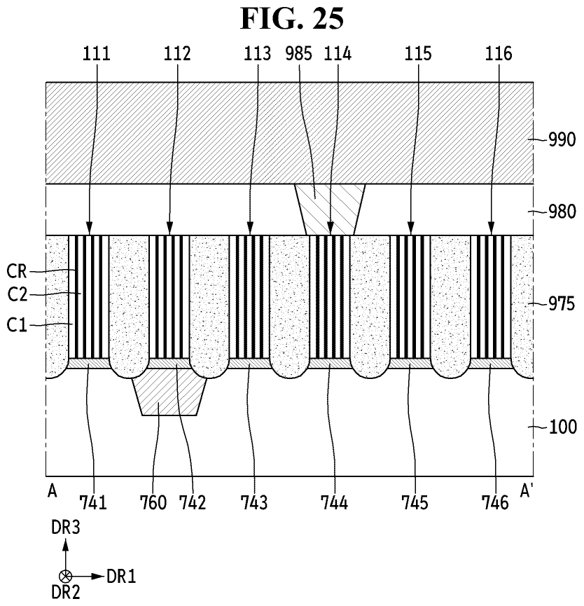

FIGS. 24 and 25 are intermediate stage diagrams for explaining the method for fabricating the semiconductor device 10H shown in FIG. 23.

Referring to FIG. 24, after performing the fabrication processes described with reference to FIGS. 16 to 21 in sequence, a second protective layer 975 may be formed on the upper surfaces of the via 760 and the substrate 100. For example, the second protective layer 975 may surround the sidewalls of each wiring pattern of the plurality of first to sixth wiring patterns 111 to 116 on the upper surface of the substrate 100 and on the upper surface of the via 760. In addition, the second protective layer 975 may surround the sidewalls of each liner pattern of the plurality of first to sixth liner patterns 741P to 746P on the upper surface of the substrate 100 and the upper surface of the via 760, respectively. For example, the second protective layer 975 may be in contact with both the upper surface of the substrate 100 and the upper surface of the via 760. As another example, the second protective layer 975 may be in contact with the sidewalls of each liner pattern of the plurality of first to sixth liner patterns 741P to 746P. The upper surface of the second protective layer 975 may be formed on the same plane as the upper surface of each wiring pattern of the plurality of first to sixth wiring patterns 111 to 116. In some embodiments, the second protective layer 975 may include, but not be limited to, at least one or more of silicon oxide (SiO₂), silicon nitride (Si₃N₄), silicon oxynitride (Si₂N₂O), or low-k dielectric material. In some exemplary embodiments, the second protective layer 975 may include, but not be limited to, spin-on hardmask (SOH).

Referring to FIG. 25, an upper interlayer insulating layer 980, an upper via 985, and an upper wiring pattern 990 may be formed on the upper surface of each of the second protective layer 975, and the plurality of first to sixth wiring patterns 111 to 116.

Referring to FIG. 23, the second protective layer 975 may be etched to form the air gap 970. The fabrication process described above with reference to FIGS. 23 to 25 may be used to fabricate the semiconductor device 10H shown in FIG. 23.

The above-described embodiments of the present disclosure are described with reference to the accompanying diagrams. However, it is to be understood that the present disclosure may not be limited to the above-described embodiments and may be fabricated in various other forms. Those of ordinary skill in the art to which the present disclosure belongs, may recognize that the present disclosure may be implemented in other specific forms without changing the technical idea or essential features of the present disclosure. Accordingly, the embodiments described above should be understood as exemplary in all respects and not as limiting.

What is claimed is:

1. A semiconductor device, comprising:
a substrate;
a first wiring pattern on an upper surface of the substrate, the first wiring pattern comprising a first crystal and a second crystal adjacent to the first crystal in a horizontal direction, a crystal orientation of each of the first crystal and the second crystal being in a vertical direction perpendicular to the upper surface of the substrate, and an interface between the first crystal and the second crystal extending in the vertical direction; and
a second wiring pattern on the upper surface of the substrate, the second wiring pattern being spaced apart from the first wiring pattern in the horizontal direction.

2. The semiconductor device of claim 1, wherein a height of the second crystal in the vertical direction is equal to a height of the first crystal in the vertical direction.

3. The semiconductor device of claim 1, wherein an upper surface of the second crystal is formed on a same plane as an upper surface of the first crystal.

4. The semiconductor device of claim 1, wherein a bottom surface of the second crystal is formed on a same plane as a bottom surface of the first crystal.

5. The semiconductor device of claim 1, wherein a distance in the horizontal direction between the first wiring pattern and the second wiring pattern is equal to a width of the first wiring pattern in the horizontal direction.

6. The semiconductor device of claim 1, further comprising:
a liner layer between a bottom surface of each of the first wiring pattern and the second wiring pattern and the upper surface of the substrate, the liner layer being in contact with the bottom surface of each of the first wiring pattern and the second wiring pattern, the liner layer being in contact with a bottom surface of each of the first crystal and the second crystal.

7. The semiconductor device of claim 6, wherein the liner layer comprises:
a first liner pattern between the bottom surface of the first wiring pattern and the upper surface of the substrate; and
a second liner pattern between the bottom surface of the second wiring pattern and the upper surface of the substrate, the second liner pattern being spaced apart from the first liner pattern in the horizontal direction.

8. The semiconductor device of claim 7, further comprising:
an upper interlayer insulating layer being in contact with an upper surface of each of the first wiring pattern and the second wiring pattern; and
an air gap formed between the first wiring pattern and the second wiring pattern, the air gap exposing a portion of each of the upper surface of the substrate and a bottom surface of the upper interlayer insulating layer.

9. The semiconductor device of claim 1, further comprising:
an interlayer insulating layer at least partially surrounding a sidewall of each of the first wiring pattern and the second wiring pattern on the upper surface of the substrate.

10. The semiconductor device of claim 1, further comprising:
a via inside the substrate, the via at least partially overlapping with the second wiring pattern in the vertical direction, the via being coupled with the second wiring pattern.

11. The semiconductor device of claim 10, wherein an upper surface of the via comprises:
a first upper surface at least partially overlapping with the second wiring pattern in the vertical direction; and
a second upper surface coupled with the first upper surface, the second upper surface being formed concave toward the via.

12. A semiconductor device, comprising:
a substrate; and
a wiring pattern on an upper surface of the substrate, the wiring pattern comprising a first crystal and a second crystal adjacent to the first crystal in a horizontal direction, a crystal orientation of each of the first crystal and the second crystal being in a vertical direction perpendicular to the upper surface of the substrate, and an interface between the first crystal and the second crystal extending in the vertical direction,
wherein a height of the second crystal in the vertical direction is equal to a height of the first crystal in the vertical direction,
wherein an upper surface of the second crystal and an upper surface of the first crystal are formed on a first plane, and
wherein a bottom surface of the second crystal and a bottom surface of the first crystal are formed on a second plane.

13. The semiconductor device of claim 12, wherein a width of the wiring pattern in the horizontal direction has a range of 1 nanometer (nm) to 20 nm.

14. The semiconductor device of claim 12, wherein a bottom surface of the wiring pattern is in contact with the upper surface of the substrate, and
wherein the bottom surface of each of the first crystal and the second crystal is in contact with the upper surface of the substrate.

15. The semiconductor device of claim 12, further comprising:
a liner layer between a bottom surface of the wiring pattern and the upper surface of the substrate, the liner layer being in contact with the bottom surface of the wiring pattern, the liner layer being in contact with the bottom surface of each of the first crystal and the second crystal.

16. A method for fabricating a semiconductor device, the method comprising:
forming a first sacrificial pattern and a second sacrificial pattern spaced apart in a horizontal direction on an upper surface of a substrate;
forming a first wiring material layer at least partially covering sidewalls and an upper surface of the first sacrificial pattern, and a second wiring material layer at least partially covering sidewalls and an upper surface of the second sacrificial pattern on the upper surface of the substrate;
forming a protective layer at least partially covering each of the first wiring material layer and the second wiring material layer;
at least partially filling a space between the first wiring material layer and the second wiring material layer on the upper surface of the substrate;
separating the first wiring material layer into a first wiring pattern and a second wiring pattern spaced apart from the first wiring pattern in the horizontal direction, and separating the second wiring material layer into a third wiring pattern and a fourth wiring pattern spaced apart from the third wiring pattern in the horizontal direction by performing a planarization process to at least partially expose the upper surface of each of the first sacrificial pattern and the second sacrificial pattern; and
etching the first sacrificial pattern, the second sacrificial pattern, and the protective layer,
wherein the forming of the first wiring material layer and the second wiring material layer comprises exposing the upper surface of the substrate between the first wiring material layer and the second wiring material layer,
wherein the first wiring material layer comprises a first crystal and a second crystal adjacent to the first crystal in the horizontal direction,
wherein a crystal orientation of each of the first crystal and the second crystal on sidewalls of the first sacrificial pattern in the horizontal direction being vertical and perpendicular to the upper surface of the substrate, and
wherein an interface between the first crystal and the second crystal on sidewalls of the first sacrificial pattern in the horizontal direction extending in the vertical direction.

17. The method of claim 16, wherein a width of the first sacrificial pattern in the horizontal direction is equal to a width of the first wiring pattern in the horizontal direction, and
wherein the width of the first sacrificial pattern in the horizontal direction is equal to a width of the second wiring pattern in the horizontal direction.

18. The method of claim 16, further comprising:
forming an upper surface of the second crystal on a same plane as an upper surface of the first crystal.

19. The method of claim 16, wherein the forming of the first sacrificial pattern and the second sacrificial pattern on the upper surface of the substrate comprises:
forming a liner layer on the upper surface of the substrate; and
forming the first sacrificial pattern and the second sacrificial pattern on an upper surface of the liner layer.

20. The method of claim 19, further comprising:
forming first to fourth liner patterns at least partially overlapping each of the first to fourth wiring patterns in the vertical direction by etching the liner layer exposed between the first to fourth wiring patterns, after etching the first sacrificial pattern, the second sacrificial pattern, and the protective layer.
